(19) United States
(12) Patent Application Publication
(10) Pub. No.: US 2026/0311970 A1
(43) Pub. Date: Oct. 8, 2026

(54) SHOWERHEAD STRUCTURE, AND SUBSTRATE PROCESSING CHAMBER AND SEMICONDUCTOR PROCESSING APPARATUS HAVING THE SAME

(71) Applicant: ASM IP Holding B.V., Almere (NL)

(72) Inventors: Vivek Upadhaya, Hwaseong (KR); DaeYoun Kim, Seo-gu (KR); Ryu Nakano, Sagamihara-shi (JP); Pilla Anand Raju, Tokyo (JP)

(21) Appl. No.: 19/637,209

(22) Filed: Apr. 2, 2026

Related U.S. Application Data
(60) Provisional application No. 63/784,475, filed on Apr. 7, 2025.

(51) Int. Cl. H01J 37/32; H10P 72/00

(52) U.S. Cl. CPC H01J 37/3244; H01J 37/32357; H01J 2237/332; H10P 72/04

(57) ABSTRACT

In one embodiment, a showerhead structure for supplying a gas to a substrate processing chamber, comprising: a first plate comprising a plurality of reactant-gas-inlet holes and at least one source-gas-inlet hole penetrating the first plate via at least one first channel, wherein the first channel is formed horizontally inside of the first plate; and a second plate comprising a recess extending from a center to a second plate edge of the second plate, a plurality of reactant-gas-outlet holes, and a plurality of source-gas-outlet holes, wherein a plurality of second channels connect the plurality of the reactant-gas-inlet holes to the plurality of the reactant-gas-outlet holes.

### CROSS-REFERENCE TO RELATED APPLICATIONS

This application claims priority to U.S. Provisional Patent Application Ser. No. 63/784,475 filed Apr. 7, 2025 and titled SHOWERHEAD STRUCTURE, AND SUBSTRATE PROCESSING CHAMBER AND SEMICONDUCTOR PROCESSING APPARATUS HAVING THE SAME, the disclosure of which is hereby incorporated by reference in its entirety.

### FIELD OF INVENTION

The present disclosure generally relates to a shower head structure, and a substrate processing chamber and a semiconductor processing apparatus having the same. More particularly, the disclosure relates to a showerhead structure to be used for a gas distribution system of a gas-phase reactor and a substrate processing chamber having the same.

### BACKGROUND OF THE DISCLOSURE

In a typical plasma process, the RF generator generates power at the desired RF frequency and power, and this power is transmitted through the RF cables and matching networks to the plasma chamber. A gas-phase reaction, such as chemical vapor deposition (CVD), plasma-enhanced CVD (PECVD), atomic layer deposition (ALD), plasma enhanced atomic layer deposition (PEALD) and the like may be used for a variety of applications, including depositing and etching materials on a substrate surface. For example, a gas-phase reaction may be used to deposit and/or etch layers on a substrate to form semiconductor devices, flat panel display devices, photovoltaic devices, microelectromechanical systems (MEMS), and the like.

A typical substrate processing chamber for the gas-phase reaction includes a reactor, one or more precursor gas sources fluidly coupled to the reactor, one or more carrier or purge gas sources fluidly coupled to the reactor, a gas distribution system to deliver a gas or gases (e.g., a precursor gas or gases, a reactant gas or gases, and/or a carrier or purge gas or gases) to a surface of a substrate, and an exhaust source fluidly coupled to the reactor. The substrate processing chamber also typically includes a susceptor to hold a substrate in place during processing the substrate. The susceptor may be configured to move up and down to receive a substrate and/or may rotate during processing the substrate.

In a substrate processing, segregation of the reactant and precursor gas flow may be important for a film quality and a film uniformity on the substrate.

Therefore, the present disclosure presents a showerhead structure, and a substrate processing chamber using the showerhead structure for segregated reactant and precursor gas flow in a substrate processing. The showerhead structure may be embodied as a dual channel showerhead structure.

### SUMMARY OF THE DISCLOSURE

This summary is provided to introduce a selection of concepts in a simplified form. These concepts are described in further detail in the detailed description of exemplary embodiments of the disclosure below. This summary is not intended to identify key features or essential features of the claimed subject matter, nor is it intended to be used to limit the scope of the claimed subject matter.

In accordance with one exemplary embodiment, there may be provided a showerhead structure for supplying a gas to a substrate processing chamber, comprising: a first plate comprising a plurality of reactant-gas-inlet holes and at least one source-gas-inlet hole penetrating the first plate via at least one first channel, wherein the first channel is formed horizontally inside of the first plate; and a second plate comprising a recess extending from a center to a second plate edge of the second plate, a plurality of reactant-gas-outlet holes, and a plurality of source-gas-outlet holes, wherein a plurality of second channels connect the plurality of the reactant-gas-inlet holes to the plurality of the reactant-gas-outlet holes.

In accordance with another exemplary embodiment, there may be provided a substrate processing chamber comprising: a reactor; a showerhead structure as described above; a susceptor disposed facing the showerhead structure; a remote plasma source disposed above the reactor; and a manifold connecting the reactor and the remote plasma source, wherein the showerhead structure supplies a gas to the substrate processing chamber, and comprises: a first plate comprising a plurality of reactant-gas-inlet holes and at least one source-gas-inlet hole penetrating the first plate via at least one first channel, wherein the first channel is formed horizontally inside of the first plate; and a second plate comprising a recess extending from a center to a second plate edge of the second plate, a plurality of reactant-gas-outlet holes, and a plurality of source-gas-outlet holes, wherein a plurality of second channels connect the plurality of the reactant-gas-inlet holes to the plurality of the reactant-gas-outlet holes.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 shows a showerhead structure in accordance with exemplary embodiments of the present disclosure.

FIG. 2 shows a first plate of the showerhead structure in accordance with exemplary embodiments of the present disclosure.

FIG. 3 shows an enlarged view of a second plate of the showerhead structure in accordance with exemplary embodiments of the present disclosure.

FIG. 4 shows a sectional view of the showerhead structure in accordance with exemplary embodiments of the present disclosure.

FIG. 5 shows a top view of the first plate of the showerhead structure in accordance with exemplary embodiments of the present disclosure.

FIG. 6 (a)-(d) shows a pattern of circular, square, hexagonal or diamond shapes.

FIG. 7 shows a bottom view of the second plate of the showerhead structure in accordance with exemplary embodiments of the present disclosure.

FIG. 8 shows the showerhead structure with a mesh in accordance with exemplary embodiments of the present disclosure.

FIG. 9 shows a top view of the first plate of the showerhead structure with the mesh in accordance with exemplary embodiments of the present disclosure.

FIG. 10 (a) shows a top view and a sectional view (bottom) of the showerhead structure 1 in accordance with exemplary embodiments of the present disclosure; (b) shows another top view of the showerhead structure 1 with a substrate position 19 indicated for a reference.

FIG. 11 (a) shows a further top view and a sectional view (bottom) of the showerhead structure 1 in accordance with exemplary embodiments of the present disclosure; (b) shows another top view of the showerhead structure 1 with a substrate position 19 indicated for a reference.

FIG. 12 shows a substrate processing chamber in accordance with exemplary embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

### Showerhead Structure

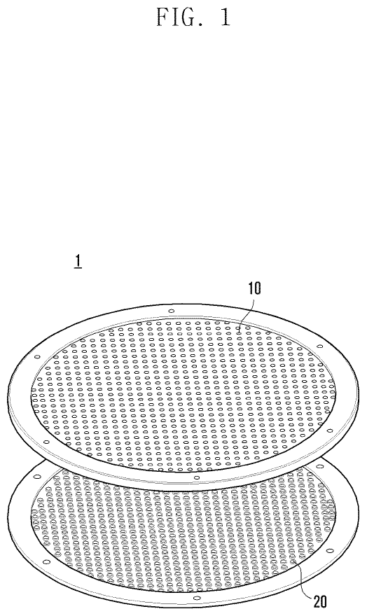

Referring to FIG. 1, a showerhead structure 1 for supplying a gas to a substrate processing chamber according to an embodiment of the present invention may include a first plate 10 and a second plate 20.

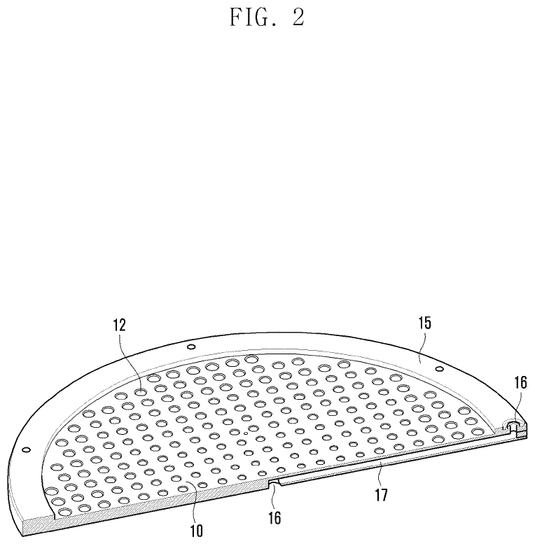

FIG. 2 shows a first plate 10 of the showerhead structure 1 in accordance with exemplary embodiments of the present disclosure. The first plate 10 may comprise a plurality of reactant-gas-inlet holes 12 and at least one source-gas-inlet hole 16 penetrating the first plate 10 via at least one first channel 17. The first channel 17 may be formed horizontally inside of the first plate 10. One end of the source-gas-inlet-hole 16 may be located on a first plate edge 15 portion of an upper side of the first plate 10, and the other end of the source gas-inlet-hole 16 may be located on an inner portion of a lower side of the first plate 10.

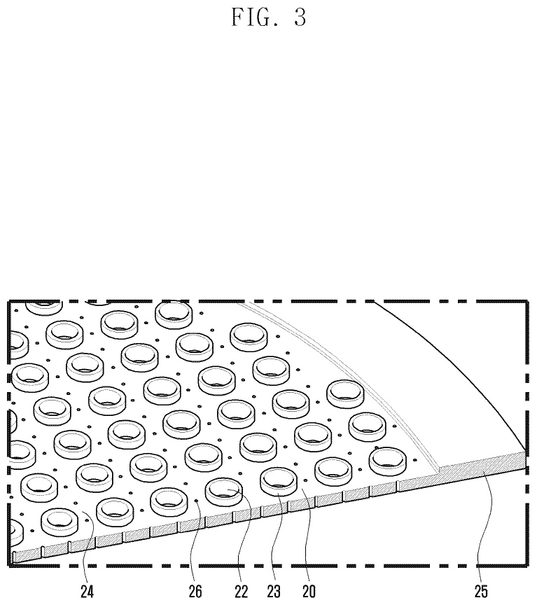

FIG. 3 shows an enlarged view of a second plate 20 of the showerhead structure 1 in accordance with exemplary embodiments of the present disclosure. The second plate 20 may comprise a recess 24 extending from a center to a second plate edge 25 of the second plate 20, a plurality of reactant-gas-outlet holes 22, and a plurality of source-gas-outlet holes 26. A plurality of second channels 23 may connect the plurality of the reactant-gas-inlet holes 12 to the plurality of the reactant-gas-outlet holes 22.

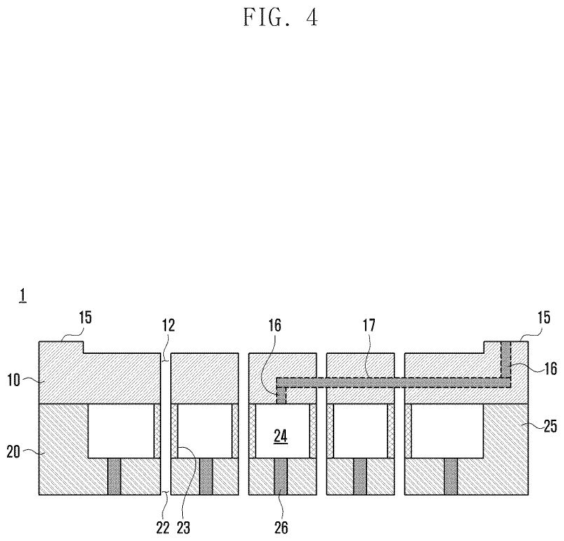

FIG. 4 shows a sectional view of the showerhead structure 1 in accordance with exemplary embodiments of the present disclosure. A reactant gas flow path may be formed between the plurality of the reactant-gas-inlet holes 12, the plurality of the second channels 23, and the plurality of the reactant-gas-outlet holes 22. And a source gas flow path may be formed between the source-gas-inlet hole 16, the first channel 17, the recess 24, and the plurality of the source-gas-outlet holes 26. A diameter of each of the reactant-gas-inlet hole 12, the reactant-gas-outlet hole 22, and an inner space of the second channel 23 may be between about 0.2 mm to about 15 mm, and a diameter of the source-gas-outlet holes 26 may be between about 0.2 mm to about 5 mm.

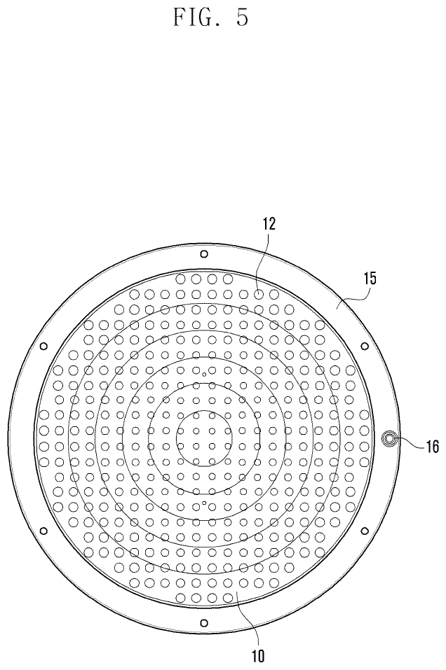

FIG. 5 shows a top view of the first plate 10 of the showerhead structure 1 in accordance with exemplary embodiments of the present disclosure. A size of each of the plurality of reactant-gas-inlet holes 12 may be variable from a center to a first plate edge 15 of the first plate 10. And the size of each of the plurality of the reactant-gas-inlet holes 12 may increase from the center to the first plate edge 15 of the first plate 10 or vice versa.

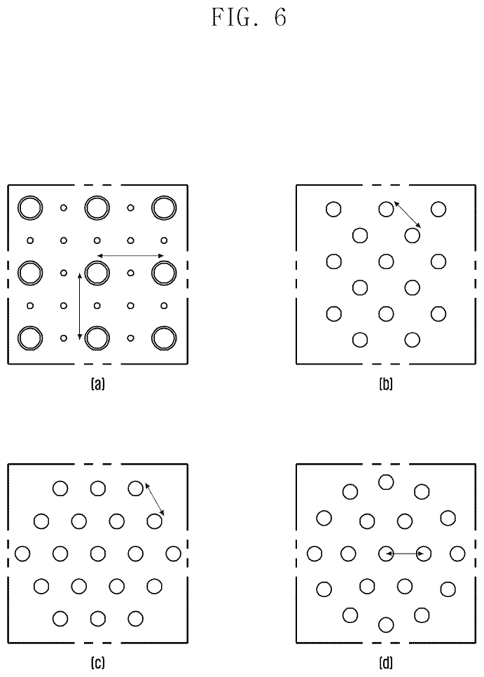

FIG. 6 (a)-6(d) shows a pattern of circular, square, hexagonal or diamond shapes. The reactant-gas-inlet holes 12 of the first plate 10 and the reactant-gas-outlet holes 22 of the second plate 20 may be arranged in a pattern of one of circular, square, hexagonal, and diamond.

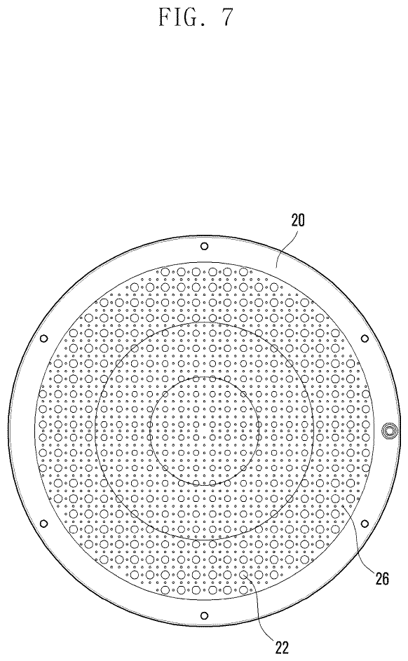

FIG. 7 shows a bottom view of the second plate 20 of the showerhead structure 1 in accordance with exemplary embodiments of the present disclosure. A size of each of the plurality of the source-gas-outlet holes 26 may be variable from a center to a second plate edge 25 of the second plate 20. And the size of each of the plurality of the source-gas-outlet holes 26 may increase from the center to the second plate edge of the second plate 20 or vice versa.

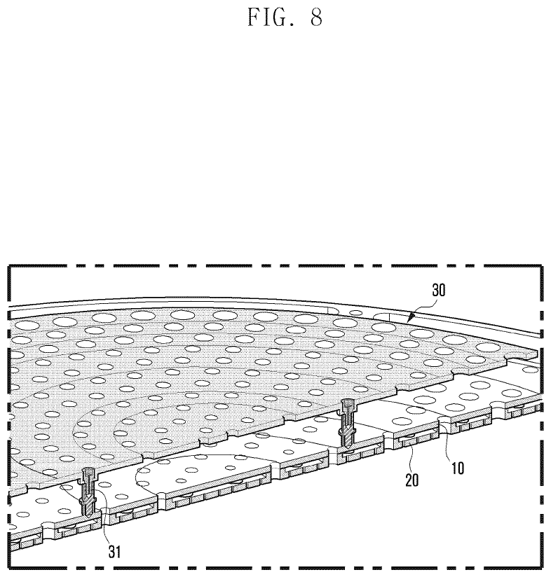

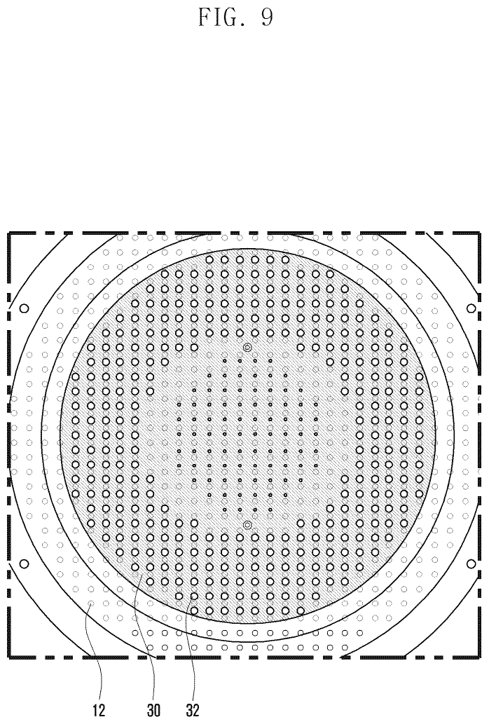

FIG. 8 shows the showerhead structure 1 with a mesh 30 in accordance with exemplary embodiments of the present disclosure, and FIG. 9 shows a top view of the first plate of the showerhead structure with the mesh in accordance with exemplary embodiments of the present disclosure. The mesh 30 may be located above the first plate 10, and may comprise a plurality of mesh holes 32. A pattern of the plurality of mesh holes 32 may be not aligned with a pattern of the plurality of the reactant-gas-inlet holes 12 of the first plate 10. The mesh 30 may be supported by at least one support 31. A thickness of the mesh 30 may be between about 1 mm to about 4 mm.

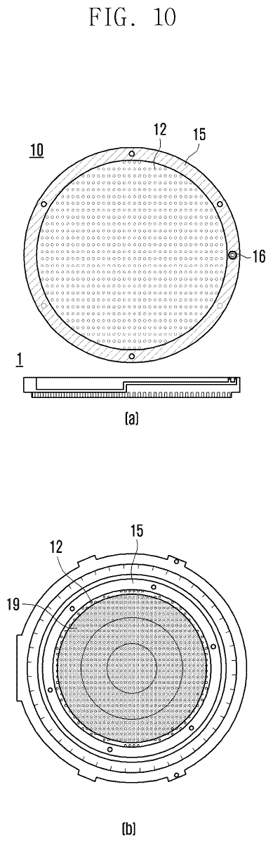

FIG. 10 (a) shows a top view and a sectional view (bottom) of the showerhead structure 1 in accordance with exemplary embodiments of the present disclosure. Only the plurality of reactant-gas-inlet holes 12 are shown, and there are no reactant-gas-inlet holes 12 around the first plate edge 15 area of the first plate 10 of the showerhead structure 1. FIG. 10 (b) shows another top view of the showerhead structure 1 with a substrate position 19 indicated for a reference. The plurality of reactant-gas-inlet holes 12 barely cover the substrate position 19, so there may be little or no radical flow near the region of the first plate edge 15. Therefore, the edge film thickness on the substrate (not shown) may be thin compared to the film thickness on an inner portion of the substrate.

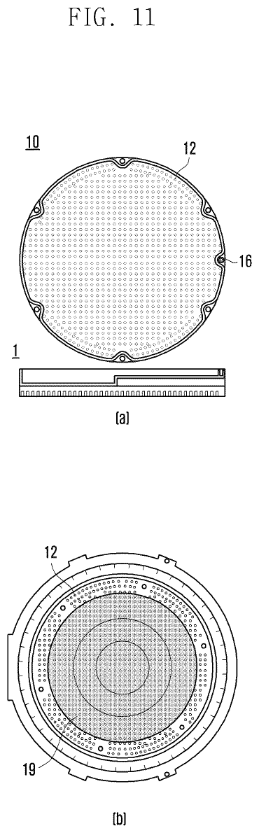

FIG. 11 (a) shows a further top view and a sectional view (bottom) of the showerhead structure 1 in accordance with exemplary embodiments of the present disclosure. In FIG. 11 (a), in addition to the plurality of reactant-gas-inlet holes 12, it is shown that additional reactant-gas-inlet holes 12, e.g., two additional circular rows of reactant-gas-inlet holes 12 are further provided near the first plate edge 15. FIG. 11 (b) shows another top view of the showerhead structure 1 with a substrate position 19 indicated for a reference. With the additional circular rows of reactant-gas-inlet holes 12 provided near the first plate edge 15, the plurality of reactant-gas-inlet holes 12 sufficiently cover the substrate position 19, so there may be sufficient flow near the region of the first plate edge 15. Therefore, a film thickness formed on the substrate (not shown) near the first plate edge 15 may increase, resulting in film uniformity improved over the substrate.

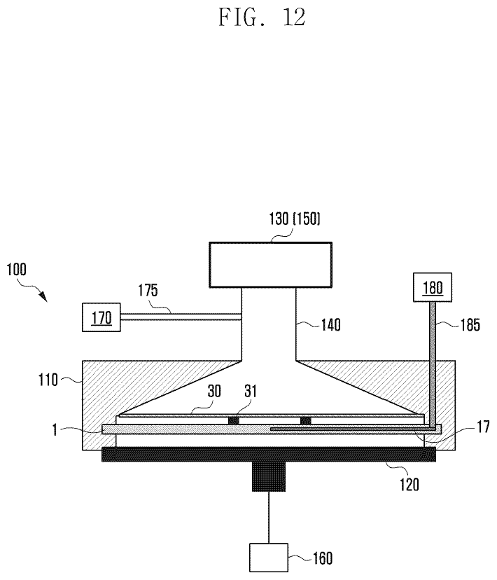

FIG. 12 shows a substrate processing chamber 100 in accordance with exemplary embodiments of the present disclosure. The substrate processing chamber 100 may comprise a reactor 110; a showerhead structure 1 as described above; a susceptor 120 disposed facing the showerhead structure 1; a remote plasma source 130 disposed above the reactor 110; and a manifold 140 connecting the reactor 110 and the remote plasma source 130. The remote plasma source 130 may comprise an inductively coupled plasma (ICP) source 150. A capacitively coupled plasma (CCP) source 160 may be coupled to the susceptor 120. The substrate processing chamber may further comprise the mesh 30 disposed between the showerhead structure 1 and the remote plasma source 130. The substrate processing chamber may further comprise a reactant-gas source 170 connected to the manifold 140 through a reactant-gas-supply pipe 175, and a source-gas source 180 connected to the first channel 17 formed horizontally inside of the first plate 10 of the showerhead structure 1 through a source-gas-supply pipe 185.

The showerhead structure 1 for supplying a gas to a substrate processing chamber according to an embodiment of the present invention may be embodied as a dual channel showerhead which provides a separate flow path to a substate (not shown herein) loaded on the susceptor 120 for the reactant gas coming from the remote plasma source 130 and the source gas without mixing each other before reaching the substrate, enabling forming a film with high quality. It also facilitates the use of a bottom bias CCP for the ICP ALD process.

The high central ion distribution produced by the ICP source 150 tends to affect the films, e.g., oxide films, nitride film, metal films, and carbide films etc., causing a non-uniformity and a damage to a film. The dual channel showerhead embodied in the showerhead structure 1 acts as an ion filter for the ICP plasma moving down to the substrate, blocking the ions but allowing neutral radicals to pass there through for a radical dominant reaction. Depending on the process requirements, the dual channel showerhead may act as an electrode and a bottom bias CCP may be used to create a uniform ion density on the substrate.

By tuning the hole size and pattern of the dual channel showerhead, the thickness and non-uniformity of the film properties to be deposited on the wafer may be controlled.

In current ICP reactor, a central high ion damage has been observed on the substrate when performing a film forming process, e.g., oxide process, nitride process, metal process, and carbide process etc. The dual channel showerhead design may help to mitigate this with tuning options available on the hole size and pattern as well as options to use bottom bias CCP in addition to the ICP. In this scenario, the high radical density generated by the ICP source would be the primary radical source to the substrate, while the ions from the ICP source would be filtered out by the dual channel showerhead. In turn, the radicals may be supplied to the substrate in a uniform manner based on process requirements by controlling the power and RF frequency through the bottom bias CCP.

In some embodiments, the reactant-gas source 170 may comprise one or more of oxygen-containing gas, nitrogen-containing gas, carbon-containing gas, hydrogen-containing gas, and the mixture thereof. The source-gas source 180 may comprise one or more of silicon-containing gas, titanium-containing gas, molybdenum-containing gas, aluminum-containing gas, tantalum-containing gas, tungsten-containing gas, and the mixture thereof depending on a precursor used.

While the present inventions have been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present inventions. Thus, the spirit and scope of the inventions should be construed broadly as set forth in the appended claims.

The above-described arrangements of a showerhead structure, and a substrate processing chamber and a semiconductor processing apparatus using the showerhead structure for segregated reactant and precursor gas flow in substrate processing are merely illustrative of applications of the principles of this invention and many other embodiments and modifications may be made without departing from the spirit and scope of the invention as defined in the claims. The scope of the present invention should, therefore, be determined not with reference to the above description, but instead should be determined with reference to the appended claims along with their full scope of equivalents.

1. A showerhead structure for supplying a gas to a substrate processing chamber, comprising:
a first plate comprising a plurality of reactant-gas-inlet holes, at least one source-gas-inlet hole penetrating the first plate via at least one first channel, wherein the first channel is formed horizontally inside of the first plate; and
a second plate comprising a recess extending from a center to an edge of the second plate, a plurality of reactant-gas-outlet holes, and a plurality of source-gas-outlet holes,
wherein a plurality of second channels connect the plurality of the reactant-gas-inlet holes to the plurality of the reactant-gas-outlet holes.

2. The showerhead structure of claim 1, wherein one end of the source-gas-inlet-hole is located on a first plate edge portion of an upper side of the first plate, and the other end of the source gas-inlet-hole is located on an inner portion of a lower side of the first plate.

3. The showerhead structure of claim 1, wherein, in addition to the plurality of reactant-gas-inlet holes, additional reactant-gas-inlet holes are further provided near the first plate edge.

4. The showerhead structure of claim 1, wherein a reactant gas flow path is formed between the plurality of the reactant-gas-inlet holes, the plurality of the second channels, and the plurality of the reactant-gas-outlet holes.

5. The showerhead structure of claim 1, wherein a source gas flow path is formed between the source-gas-inlet hole, the first channel, the recess, and the plurality of the source-gas-outlet holes.

6. The showerhead structure of claim 1, wherein a size of each of the plurality of reactant-gas-inlet holes is variable from a center to a first plate edge of the first plate.

7. The showerhead structure of claim 6, wherein the size of each of the plurality of the reactant-gas-inlet holes increases from the center to the first plate edge of the first plate or vice versa.

8. The showerhead structure of claim 1, wherein a size of each of the plurality of the source-gas-outlet holes is variable from a center to the second plate edge of the second plate.

9. The showerhead structure of claim 8, wherein the size of each of the plurality of the source-gas-outlet holes increases from the center to the second plate edge of the second plate or vice versa.

10. The showerhead structure of claim 1, wherein the reactant-gas-inlet holes of the first plate and the reactant-gas-outlet holes of the second plate are arranged in a pattern of one of circular, square, hexagonal, and diamond.

11. The showerhead structure of claim 1, wherein a diameter of each of the reactant-gas-inlet hole, the reactant-gas-outlet hole, and an inner space of the second channel is between about 0.2 mm to about 15 mm.

12. The showerhead structure of claim 1, wherein a diameter of the source-gas-outlet holes is between about 0.2 mm to about 5 mm.

13. The showerhead structure of claim 1, further comprising a mesh located above the first plate.

14. A substrate processing chamber comprising:
a reactor;
a showerhead structure;
a susceptor disposed facing the showerhead structure;
a remote plasma source disposed above the reactor; and
a manifold connecting the reactor and the remote plasma source,
wherein the showerhead structure comprises:
a first plate comprising a plurality of reactant-gas-inlet holes, at least one source-gas-inlet hole penetrating the first plate via at least one first channel, wherein the first channel is formed horizontally inside of the first plate; and
a second plate comprising a recess extending from a center to a second plate edge of the second plate, a plurality of reactant-gas-outlet holes, and a plurality of source-gas-outlet holes, wherein a plurality of second channels connect the plurality of the reactant-gas-inlet holes to the plurality of the reactant-gas-outlet holes.

15. The substrate processing chamber of claim 14, wherein the remote plasma source comprises an inductively coupled plasma source.

16. The substrate processing chamber of claim 14, further comprising a capacitively coupled plasma source coupled to the susceptor.

17. The substrate processing chamber of claim 14, further comprising a mesh disposed between the showerhead structure and the remote plasma source, wherein the mesh comprises a plurality of mesh holes, and a pattern of the plurality of mesh holes is not aligned with a pattern of the plurality of the reactant-gas-inlet holes of the first plate.

18. The substrate processing chamber of claim 17, further comprising at least one support supporting the mesh.

19. The substrate processing chamber of claim 17, wherein a thickness of the mesh is between about 1 mm to about 4 mm.

20. The substrate processing chamber of claim 14, further comprising a reactant-gas source connected to the manifold through a reactant-gas-supply pipe, and a source-gas source connected to the first channel formed horizontally inside of the first plate of the showerhead structure through a source-gas-supply pipe.

21. A semiconductor processing apparatus comprising a substrate processing chamber of claim 14.
